(19) United States
(12) Patent Application Publication
(10) Pub. No.: US 2007/0019480 A1
(43) Pub. Date: Jan. 25, 2007

(54) Test circuitry and testing methods

(75) Inventors: Dustin L. Conner, Boise, ID (US); Mark Hutchinson, Boise, ID (US); Scott N. Gatzemeier, Boise, ID (US); Kenneth W. Marr, Boise, ID (US); Jason Andrus, Boise, ID (US); Colby G. Hansen, Boise, ID (US); Theodore T. Pekny, Milpitas, CA (US); Tyson Stichka, Boise, ID (US)

Correspondence Address: LEFFERT JAY & POLGLAZE, P.A.;Attn: Tod A. Myrum, P.O. Box 581009, Minneapolis, MN, 55402, US

(73) Assignee: Micron Technology, Inc.

(21) Appl. No.: 11/185,079

(22) Filed: Jul. 20, 2005

(51) Int. Cl. G11C 7/06; G11C 7/02

(52) U.S. Cl. 365/189.07; 365/210

(57) ABSTRACT

A memory device compares, within the memory device, a signal indicative of a current drawn by one or more select lines to a reference signal, and indicates whether the signal indicative of the current drawn by the one or more select lines exceeds the reference signal.

### TECHNICAL FIELD OF THE INVENTION

The present invention relates generally to memory devices and in particular the present invention relates to test circuitry and testing methods for memory devices.

### BACKGROUND OF THE INVENTION

Memory devices are typically provided as internal storage areas in computers. The term memory identifies data storage that comes in the form of integrated circuit chips. In general, memory devices contain an array of memory cells for storing data, and row and column decoder circuits coupled to the array of memory cells for accessing the array of memory cells in response to an external address.

One type of memory is a non-volatile memory known as flash memory. A flash memory is a type of EEPROM (electrically-erasable programmable read-only memory) that can be erased and reprogrammed in blocks. Many modern personal computers (PCs) have their BIOS stored on a flash memory chip so that it can easily be updated if necessary. Such a BIOS is sometimes called a flash BIOS. Flash memory is also popular in wireless electronic devices because it enables the manufacturer to support new communication protocols as they become standardized and to provide the ability to remotely upgrade the device for enhanced features.

A typical flash memory comprises a memory array that includes a large number of memory cells arranged in row and column fashion. Each of the memory cells includes a floating-gate field-effect transistor capable of holding a charge. The cells are usually grouped into blocks. Each of the cells within a block can be electrically programmed on an individual basis by charging the floating gate. The charge can be removed from the floating gate by a block erase operation. The data in a cell is determined by the presence or absence of the charge on the floating gate.

NOR and NAND flash memory devices are two common types of flash memory devices, so called for the logical form the basic memory cell configuration in which each is arranged. Typically, for NOR flash memory devices, the control gate of each memory cell of a row of the array is connected to a word line, and the drain region of each memory cell of a column of the array is connected to a bit line. The memory array for NOR flash memory devices is accessed by a row decoder activating a row of floating gate memory cells by selecting the word line connected to their control gates. The row of selected memory cells then place their data values on the column bit lines by flowing a differing current, depending upon their programmed states, from a connected source line to the connected column bit lines.

The array of memory cells for NAND flash memory devices is also arranged such that the control gate of each memory cell of a row of the array is connected to a word line. However, each memory cell is not directly connected to a column bit line by its drain region. Instead, the memory cells of the array are arranged together in strings (often termed NAND strings), e.g., of 32 each, with the memory cells connected together in series, source to drain, between a source line and a column bit line. The memory array for NAND flash memory devices is then accessed by a row decoder activating a row of memory cells by selecting the word line connected to a control gate of a memory cell. In addition, the word lines connected to the control gates of unselected memory cells of each string are driven to operate the unselected memory cells of each string as pass transistors, so that they pass current in a manner that is unrestricted by their stored data values. Current then flows from the source line to the column bit line through each series connected string, restricted only by the selected memory cells of each string. This places the current-encoded data values of the row of selected memory cells on the column bit lines.

Defects can occur during the manufacture of a flash memory array having rows and columns of memory cells, such as shorts between a word line and a bit line. Shorts typically occur because of the large number of rows and columns of memory cells that have to be placed in close proximity to each other on an integrated circuit wafer. In these increasingly tighter geometries, alignment errors and other processing imperfections can lead to shorts between adjacent structures. Such defects can reduce the yield of the flash memory device.

After a memory die has been manufactured, it is tested for shorts between word lines and bit lines. In general, this testing helps with repair and/or identification of defects that can render the device inoperable. Due to shrinking cell geometries and increased word line to bit line voltage potentials during erase cycles, the density of shorts between word lines and bit lines has increased, and conventional test methods are becoming excessively time consuming.

For the reasons stated above, and for other reasons stated below which will become apparent to those skilled in the art upon reading and understanding the present specification, there is a need in the art for alternatives to conventional test methods for testing for shorts between word lines and bit lines.

### SUMMARY

The above-mentioned problems with conventional test methods for detecting shorts between word lines and bit lines and other problems are addressed by the present invention and will be understood by reading and studying the following specification.

For one embodiment, the invention provides a method of testing a memory device that includes comparing a signal indicative of a current drawn by one or more select lines to a reference signal generated within the memory device, and indicating whether the signal indicative of the current drawn by the one or more select lines exceeds the reference signal.

For another embodiment, the invention provides a memory device having a memory array having a plurality of select lines. Testing circuitry is coupled to the select lines. The testing circuitry includes a comparator. The comparator compares a signal indicative of a current drawn by one or more of the select lines to a reference signal generated within the memory device. The comparator indicates whether the signal indicative of the current drawn by the one or more select lines exceeds the reference signal.

Further embodiments of the invention include methods and apparatus of varying scope.

### BRIEF DESCRIPTION OF THE DRAWINGS

FIG. 1 is a block diagram illustration of a memory device, according to an embodiment of the invention.

FIG. 2 is a schematic of a portion of a non-volatile memory block coupled to a comparator in accordance with another embodiment of the invention.

FIG. 3 is a schematic diagram of test circuitry, according to another embodiment of the invention.

FIG. 4 is a flowchart of a method of testing a memory device, according to another embodiment of the invention.

### DETAILED DESCRIPTION

In the following detailed description of the invention, reference is made to the accompanying drawings that form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof.

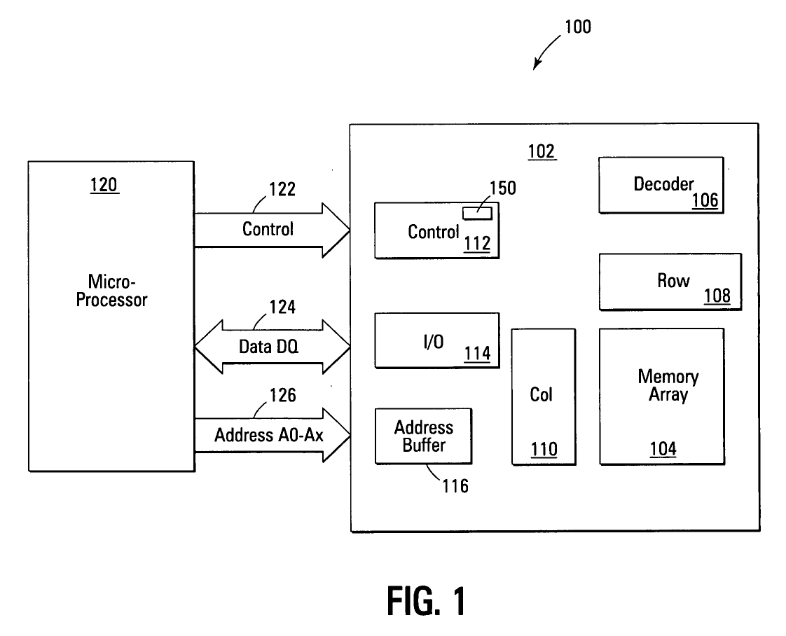

FIG. 1 is a block diagram illustration of a memory device 102, according to an embodiment of the invention. The memory device 102 may be fabricated as semiconductor device on a semiconductor substrate. Examples of memory devices include NAND or NOR non-volatile memory devices, dynamic random access memory devices (DRAMs), static random access memory devices (SRAMs), or the like.

For one embodiment, memory device 102 includes an array of memory cells 104, an address decoder 106, row access circuitry 108, column access circuitry 110, control circuitry 112, Input/Output (I/O) circuitry 114, and an address buffer 116.

Memory device 102 may be coupled with an external microprocessor 120, or memory controller, for memory accessing as part of an electronic system 100. The memory device 102 receives control signals from the processor 120 over a control link 122. The memory cells are used to store data that are accessed via a data (DQ) link 124. Address signals are received via an address link 126 that are decoded at address decoder 106 to access the memory array 104. Address buffer circuit 116 latches the address signals. The memory cells are accessed in response to the control signals and the address signals. It will be appreciated by those skilled in the art that additional circuitry and control signals can be provided, and that the memory device of FIG. 1 has been simplified to help focus on the invention.

The memory array 104 includes memory cells arranged in row and column fashion. For one embodiment, each of the memory cells includes a floating-gate field-effect transistor capable of holding a charge. The cells may be grouped into blocks. Each of the cells within a block can be electrically programmed on an individual basis by charging the floating gate. The charge can be removed from the floating gate by a block erase operation.

For one embodiment, control circuitry 112 includes test circuitry 150 for testing for word line to bit line shorts in memory array 104. This involves comparing a reference current generated within the memory device to a current indicative of a current flowing through one or more word lines of memory array 104 when a test voltage, e.g., about five volts, is applied to the one or more word lines and one or more corresponding bit lines are grounded. Alternatively, the reference current may be generated externally of the memory device and supplied to an input pad of the memory device. When the word line indicator current exceeds the reference current, test circuitry 150 outputs a first logic value, such as logic high, indicative a short between a word line and a bit line. Otherwise, test circuitry 150 outputs a second logic value, such as logic low, indicative that there are no shorts detected between the word lines and the bit lines. For another embodiment, the output of test circuitry 150 is sent to an input/output pad (not shown in FIG. 1) of memory device 102 for coupling to DQ link 124.

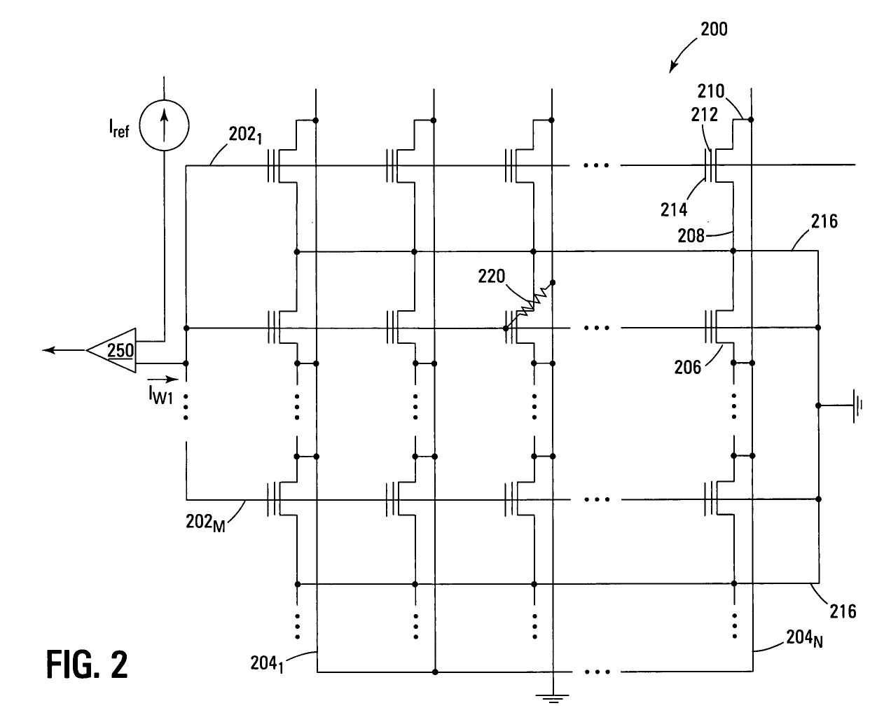

FIG. 2 is a schematic of a portion of a non-volatile memory block 200 as a portion of memory array 104 in accordance with another embodiment of the invention. Arrays of non-volatile memory cells are often configured as floating gate transistors placed at the intersection of word lines and bit lines. The word lines are coupled to control gates of the floating gate transistors, and the bit lines are coupled to drains of the floating gate transistors.

The detail of memory block 200 is provided to better understand the various embodiments of the invention. However, the invention is not limited to the specific floating-gate memory cell and layout described with reference to FIG. 2.

As shown in FIG. 2, the memory block 200 includes word lines (or word select lines) 202₁ to 202_{M} and intersecting local bit lines 204₁ to 204_{N}. For ease of addressing in the digital environment, the number of word lines 202 and the number of bit lines 204 are typically each some power of two, e.g., 256 word lines 202 by 4,096 bit lines 204. The local bit lines 204 are typically coupled to global bit lines (not shown in FIG. 2) in a many-to-one relationship.

Floating gate transistors 206 are located at each intersection of a word line 202 and a local bit line 204. The floating gate transistors 206 represent the non-volatile memory cells for storage of data. Typical construction of such floating gate transistors 206 include a source 208 and a drain 210, a floating gate 212, and a control gate 214.

Floating gate transistors 206 having their control gates 214 coupled to a word line 202 typically share a common source 208 depicted as array source 216. As shown in FIG. 2, floating gate transistors 206 coupled to two adjacent word lines 202 may share the same array source 216. Floating gate transistors 206 have their drains 210 coupled to a local bit line 204. A column of the floating gate transistors 206 are those transistors commonly coupled to a given local bit line 204. A row of the floating gate transistors 206 are those transistors commonly coupled to a given word line 202.

It should be noted that although FIG. 2 depicts a block of a NOR memory array, the invention can also be applied to NAND memory arrays, which are well understood in the art. Typically, a NAND memory array is arranged such that a control gate of each memory cell of a row of the array is connected to a word-select line. Columns of the array include strings (often termed NAND strings) of memory cells connected together in series, source to drain, between a pair of select lines, a source select line and a drain select line. The source select line includes a source select gate at each intersection between a NAND string and the source select line, and the drain select line includes a drain select gate at each intersection between a NAND string and the drain select line. The select gates are typically field-effect transistors. Each source select gate is connected to a source line, while each drain select gate is connected to a column bit line. The drain select lines and source select lines are typically formed concurrently with and parallel to the word lines, and often have substantially similar construction. Hereinafter the term “select line” will include word lines (or word select lines) of NAND and NOR memory arrays and drain select lines and source select lines of NAND memory arrays.

A resistor 220 coupled between a select line 202 and a bit line 204 is intended to exemplify a resistive short between that select line 202 and that bit line 204. Select lines 202 are coupled to a comparator 250 and bit lines 204 are coupled to ground to test for shorts between select lines 202 and bit lines 204. During a test, a test voltage, e.g., five volts, is applied to all of the select lines 202 to be tested, while bit lines 204 corresponding to the select lines 202 to be tested and array sources 216 are grounded. This causes a word line indicator current I_{wl} that is indicative of, e.g., proportional to, current flowing through one or more of the select lines 202 to be compared to a reference current I_{ref}, generated within the memory device, at comparator 250. When the word line indicator current I_{wl} exceeds the reference current I_{ref}, comparator 250 outputs a signal having a logic value, such as logic high, indicative a short to a select line. Otherwise, comparator 250 outputs a logic value, such as logic low, indicating that there are no shorts to the select lines. Although shorts are often located between a select line and an intersecting bit line, as conceptually depicted by resistor 220, other shorts to select lines 202 may be detected. Shorts, such as a short between a substrate on which a NAND array is formed through a gate dielectric layer of a select line coupled to a select gate of a NAND memory array may also be detected as described above. Hereinafter the term “shorts” will refer to any short to a select line 202 leading to a current loss in response to application of the test voltage.

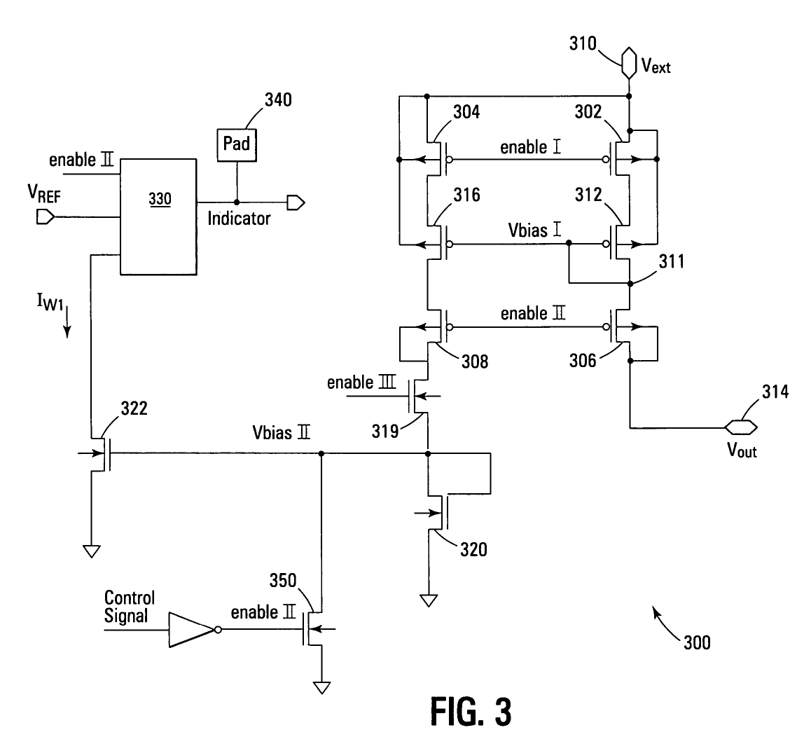

FIG. 3 is a schematic diagram of test circuitry 300, according to an embodiment of the invention. Test circuitry 300 is enabled when a test mode, e.g., of memory device 102, is enabled, such as by a control signal going high. For one embodiment, the control signal toggles between a supply voltage (Vcc), or logic HIGH, for enabling the test mode and ground (Vss), or logic LOW, for disabling the test mode. The signal voltages are tabulated in Table 1, for one embodiment, when test circuitry 300 is enabled (ON) or disabled (OFF).

TABLE 1

| Signal | OFF | ON |
|---|---|---|
| control | LOW (Vss) | HIGH (Vcc) |
| enable II | HIGH | LOW |
| enable III | LOW | Vₑₓₜ |
| enable I | Vₑₓₜ | LOW |
| Vₑₓₜ | Vₑₓₜ | Vₑₓₜ |
| Vₒᵤₜ | Hi-Z | Vselect |

In Table 1, for one embodiment, “Hi-Z” corresponds to a non-driven voltage.

When the test mode is enabled, p-channel field-effect transistors (pFETs) 302 and 304 are enabled by a first enable signal enable I_going LOW, and pFETs 306 and 308 are enabled by a second enable signal enable II going LOW. An external supply voltage Vₑₓₜ, e.g., about 5 to 6 volts, is applied to node 310, and an output voltage signal Vₒᵤₜ supplies a voltage Vselect at output node 314 to the select lines that is generally somewhat less than the external supply voltage Vₑₓₜ due to a slight voltage drop across pFETs 302, 312, and 306. When there is no short, the steady-state current thru pFET 312 is substantially zero as the select lines would form an open circuit. However, if there is a short, a leakage path results that causes a first gate bias voltage VbiasI at node 311 to drop to a level indicative of the level of current flow thru pFET 312. It will be recognized that pFETs 302, 312 and 306 form a reference leg of a current mirror while pFETs 304, 316 and 308 form a mirror leg of the current mirror. As a result, the current flow thru pFET 312 is mirrored through pFET 316. This current is selectively passed to n-channel field-effect transistor (nFET) 320 thru nFET 319. With its drain coupled to its gate, the mirrored current applied to the drain of nFET 320 will produce a second gate bias voltage VbiasII that is indicative of the level of current flow through nFET 320. The second gate bias voltage VbiasII is, in turn, applied to the gate of nFET 322. By biasing the drain of nFET 322 and coupling its source to a ground potential node, a current, I_{wl}, will be generated that is indicative of a level of current flow through the leakage path. It should be noted that when the second enable signal enable II is HIGH, nFET 350 connects second gate bias voltage VbiasII to ground, thus turning off nFET 320 and nFET 322.

Note that for one embodiment, the reference leg and the mirror leg of the current mirror are sized substantially the same, i.e., pFETs 302 and 304 are substantially the same size, pFETs 312 and 316 are substantially the same size, and pFETs 306 and 308 are substantially the same size to facilitate mirroring of the current through the leakage path. For a further embodiment, the nFETs 320 and 322 are substantially the same size to facilitate establishing I_{wl} at a level that is directly proportional to the current through the leakage path. For another embodiment, pFETs 302, 312, and 306 are respectively proportional in size to pFETs 304, 316, and 308.

The drain of nFET 322 is biased to, e.g., about 0.7 volts, thru a comparator (or sense amp circuit) 330, for one embodiment, causing the select line indicator current I_{wl} to flow through nFET 322. The select line indicator current I_{wl} thru nFET 322 is compared inside comparator 330 to the reference current I_{ref}, generated within comparator 330 in response to a reference voltage V_{REF}. For another embodiment, the reference current I_{ref} may be generated externally and supplied to an input pad of the memory device. A variety of methods for sensing current differences are known and the invention is not limited to a specific method.

Inside comparator 330, V_{REF} is placed, for example, on a gate of an nFET with a grounded source and a drain biased to the biasing voltage on the drain of nFET 322, e.g., about 0.7 volts. When the select line indicator current I_{wl} is greater than the reference current I_{ref}, comparator 330 indicates a short by setting an indicator signal Indicator, such as a digital output signal, having a logic value, such as a logic HIGH, indicative of a short on the selected select line or memory block(s). Otherwise, comparator 330 indicates that the selected select line or memory block(s) is okay or “good” by setting the indicator signal Indicator to another logic value, such as a logic LOW. For one embodiment, the indicator signal Indicator is sent to an input/output pad 340 of the memory device.

The reference current I_{ref} may be a predetermined value chosen to be indicative of an acceptable level of current leakage given the number of select lines under test, accepting that some level of current leakage is generally inevitable even if no short is present. Higher values of I_{ref} are generally deemed to be acceptable if multiple select lines are being tested than if a single select line is being tested. However, the value of I_{ref} for the testing of multiple select lines would generally not be equal to the product of I_{ref} for testing of a single select line times the number of select lines under test. The value of the reference current I_{ref} should generally be chosen such that it is approximately equal to or greater than the expected current leakage if no short is present in the select lines under test, but less than an expected current leakage if at least one short is present. For other embodiments, the reference current I_{ref} is adjustable.

For one embodiment, the value of the reference voltage V_{REF} can be determined by selecting a voltage that produces reference current I_{ref} that is substantially equal to a select line indicator current I_{wl} for a known “good” select line or memory block(s) that does not have a short. For another embodiment, the reference voltage V_{REF} may be supplied externally to an input pad of the memory device or generated internally within the memory device.

For some embodiments, the select line indicator current I_{wl} is passed through a resistor (not shown), and the resulting voltage drop across the resistor is compared to the reference voltage V_{REF}. If the reference voltage V_{REF} is greater than or equal to the resulting voltage drop across the resistor, the select line is shorted, i.e., either to a bit line or an oxide layer of the select line coupled a select gate of a NAND memory array is shorted to a substrate. It will be appreciated by those skilled in the art that there are other ways of determining if a signal indicative of the current drawn through the select line(s) is greater than a desired level, whether comparing it to a reference current or voltage level.

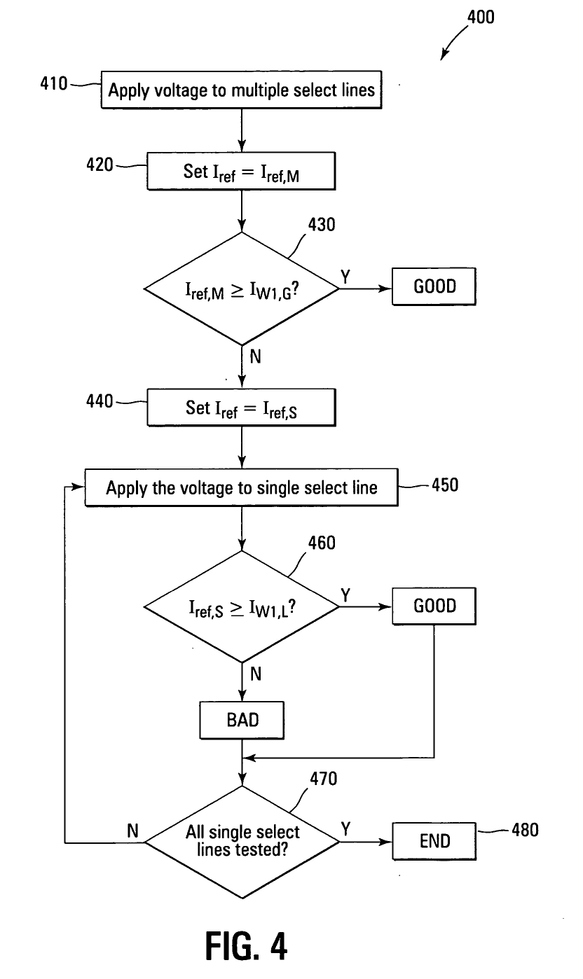

FIG. 4 is a flowchart of a method 400 of testing a memory device, according to another embodiment of the invention. At block 410, the voltage Vselect is applied to multiple select lines, such as a block of select lines that may include select lines coupled to select gates of a NAND memory array, and the reference current I_{ref} is set to an acceptable level of current leakage I_{ref,M} for the multiple select lines at block 420. If I_{ref,M} is greater than or equal to a global current I_{wl,G} drawn by the multiple select lines in response to Vselect at decision block 430, then no shorts are detected and the multiple select lines are denoted as “GOOD.” If I_{ref,M} is less than the global current I_{wl,G}, the multiple select lines are denoted as “BAD.” Optionally, if I_{ref,M} is less than the global current I_{wl,G}, the reference current I_{ref} is set to an acceptable level of current leakage I_{ref,S} for a single select line, at block 440, and Vselect is applied to the single select line, at block 450. If I_{ref,S} is greater than or equal to a local current I_{wl,L} drawn by the single select line in response to Vselect at decision block 460, then no short is detected, and the single select line is denoted as “GOOD.” Otherwise, the select line is deemed to have a short and is denoted as “BAD.” The method then proceeds to decision block 470 to determine whether each of the single select lines of the multiple select lines has been individually tested. If each of the single select lines has not been individually tested, the method returns to block 450 and another single select line is individually tested. If each of the single select lines has been tested individually, the method ends at block 480.

### CONCLUSION

For one embodiment, a memory device compares a signal indicative of a current drawn by one or more select lines to a reference signal generated within the memory device, and indicates whether the signal indicative of the current drawn by the one or more select lines exceeds the reference signal. This is considerably less time consuming than conventional testing and can reduce test times by as much as a factor of about 8 to a factor of about 240.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

What is claimed is:

1. A method of testing a memory device, comprising:
within the memory device, comparing a signal indicative of a current drawn by one or more select lines to a reference signal; and
indicating whether the signal indicative of the current drawn by the one or more select lines exceeds the reference signal.

2. The method of claim 1, wherein indicating whether the signal indicative of the current drawn by the one or more select lines exceeds the reference signal comprises outputting a logic value.

3. The method of claim 1 further comprises indicating a short if the signal indicative of the current drawn by the one or more select lines exceeds the reference signal.

4. The method of claim 1, wherein signal indicative of a current drawn by one or more select lines is either a voltage or a current and the reference signal is a reference voltage or a reference current.

5. The method of claim 1, wherein the select lines comprise one or more lines selected from the group consisting of word lines, drain select lines, and source select lines.

6. The method of claim 1, wherein the reference signal is adjustable.

7. The method of claim 1, wherein the reference signal is generated within the memory device or externally of the memory device.

8. A method of testing a memory device, comprising:
generating a signal indicative of a current drawn by one or more select lines;
within the memory device, comparing the signal indicative of the current drawn by the one or more select lines to a reference signal; and
indicating whether the signal indicative of the current drawn by the one or more select lines exceeds the reference signal.

9. The method of claim 8, wherein indicating whether the signal indicative of the current drawn by the one or more select lines exceeds the reference signal comprises outputting a logic value.

10. The method of claim 8 further comprises indicating a short if the signal indicative of the current drawn by the one or more select lines exceeds the reference signal.

11. The method of claim 8, wherein generating a signal indicative of a current drawn by one or more select lines comprises mirroring the current drawn by the one or more select lines.

12. The method of claim 8 further comprises grounding one or more bit lines corresponding to the one or more select lines while applying a voltage to the one or more select lines.

13. The method of claim 8, wherein signal indicative of a current drawn by one or more select lines is either a voltage or a current and the reference signal is a reference voltage or a reference current.

14. The method of claim 8 wherein the select lines comprise one or more lines selected from the group consisting of word lines, drain select lines, and source select lines.

15. A method of testing a memory device, comprising:
generating a first current indicative of a global current drawn by select lines of a memory block of the memory device;
within the memory device, comparing the first current indicative of the global current to a first reference current; and
if the first current indicative of the global current exceeds the first reference current, performing a method on each select line of the memory block, comprising:
generating a second current indicative of a local current drawn by the select line;
within the memory device, comparing the second current indicative of the local current to a second reference current; and
indicating whether the second current indicative of the local current exceeds the second reference current.

16. The method of claim 15 further comprises indicating a likelihood of a short somewhere on the memory block if the first current indicative of the global current exceeds the first reference current.

17. The method of claim 16 further comprises if the first current indicative of the global current exceeds the first reference current, indicating that the select line is shorted if the second current indicative of the local current drawn by the select line exceeds the second reference current.

18. A method of testing a memory device, comprising:
mirroring a first current drawn by one or more select lines and applying the mirrored current to a drain and gate of a first n-channel field-effect transistor having a source coupled to a ground potential node, thereby generating a first bias potential at the gate of the first n-channel field-effect transistor indicative of the first current;
applying the first bias potential to the gate of a second n-channel field-effect transistor having a drain biased to a second bias potential and a source coupled to a ground potential node, thereby generating a second current;
generating a reference current;
comparing the second current to the reference current within the memory device; and
indicating whether the second current exceeds the reference current.

19. The method of claim 18, wherein indicating whether the current indicative of the current drawn by one or more select lines exceeds the reference current comprises outputting a logic value.

20. The method of claim 18 further comprises indicating a short if the current indicative of the current drawn by the one or more select lines exceeds the reference current.

21. A memory device comprising:
a memory array having a plurality of select lines; and
testing circuitry coupled to the select lines, wherein the testing circuitry comprises a comparator;
wherein the comparator compares a signal indicative of a current drawn by one or more of the select lines to a reference signal within the memory device; and
wherein the comparator indicates whether the signal indicative of the current drawn by the one or more select lines exceeds the reference signal.

22. The memory device of claim 21, wherein the comparator indicates whether the signal indicative of the current drawn by the one or more select lines exceeds the reference signal by outputting a logic value.

23. The memory device of claim 21, wherein an output of the comparator is coupled to an input/output pad of the memory device.

24. The memory device of claim 21, wherein some of the select lines are word lines that intersect bit lines, wherein each intersection of a word line and a bit line defines a memory cell of the memory device.

25. The memory device of claim 24, wherein the memory cells are arranged in rows and columns.

26. The memory device of claim 25, wherein each column of the array includes a string of memory cells connected together in series between a pair of other of the select lines.

27. The memory device of claim 21, wherein the signal indicative of a current drawn by one or more select lines is either a voltage or a current and the reference signal is a reference voltage or a reference current.

28. The memory device of claim 21, wherein the reference signal is adjustable.

29. A memory device comprising:
a memory array having a plurality of select lines, wherein some of the plurality select lines intersect bit lines, wherein each intersection of a select line and a bit line defines a memory cell of the array; and
test circuitry coupled to each of the plurality of select lines, the test circuitry comprising:
a current mirror having a reference leg and a mirror leg, wherein the reference leg of the current mirror is coupled to each of the plurality of select lines;
a first n-channel field-effect transistor having a drain and a gate coupled to the mirror leg of the current mirror and a source coupled to a ground potential node; and
a second n-channel field-effect transistor having a gate coupled to the gate of the first n-channel field-effect transistor, a source coupled to a ground potential node and a drain; and
a comparator for comparing a current draw thru the second n-channel field-effect transistor to a reference current, and providing an output signal indicative of whether the current draw thru the second n-channel field-effect transistor is greater than the reference current.

30. The memory device of claim 29, wherein the reference leg of the current mirror is sized substantially the same as the mirror leg of the current mirror.

31. The memory device of claim 29, wherein the comparator is further adapted to generate the reference current.

32. The memory device of claim 29, wherein the first and second n-channel field-effect transistors are sized substantially the same.

33. The memory device of claim 29, wherein an output of the comparator is coupled to an input/output pad of the memory device.

34. The memory device of claim 29, wherein the memory device is a NAND or a NOR non-volatile memory device or an SRAM or DRAM memory device.

35. A non-volatile memory device comprising:
a memory array having a plurality of select lines; and
testing circuitry coupled to the select lines, wherein the testing circuitry comprises a comparator;
wherein the comparator compares a signal indicative of a current drawn by one or more of the select lines to a reference signal within the memory device; and
wherein the comparator indicates whether the signal indicative of the current drawn by the one or more select lines exceeds the reference signal.

36. The non-volatile memory device of claim 35, wherein the comparator indicates whether the signal indicative of the current drawn by the one or more select lines exceeds the reference signal by outputting a logic value.

37. The non-volatile memory device of claim 35, wherein an output of the comparator is coupled to an input/output pad of the memory device.

38. The non-volatile memory device of claim 35, wherein some of the select lines are word lines that intersect bit lines, wherein each intersection of a word line and a bit line defines a memory cell of the memory device.

39. The non-volatile memory device of claim 38, wherein the memory cells are arranged in rows and columns.

40. The non-volatile memory device of claim 39, wherein each column of the array includes a string of memory cells connected together in series between a pair of other of the select lines.

41. The non-volatile memory device of claim 35, wherein the signal indicative of a current drawn by one or more select lines is either a voltage or a current and the reference signal is a reference voltage or a reference current.

42. The non-volatile memory device of claim 35, wherein the reference signal is adjustable.

43. An electronic system, comprising:
a processor; and
a memory device coupled to the processor and comprising:
a memory array having a plurality of select lines; and
testing circuitry coupled to the select lines, wherein the testing circuitry comprises a comparator;
wherein the comparator compares a signal indicative of a current drawn by one or more of the select lines to a reference signal within the memory device; and
wherein the comparator indicates whether the signal indicative of the current drawn by the one or more select lines exceeds the reference signal.

44. The electronic system of claim 43, wherein the comparator indicates whether the signal indicative of the current drawn by the one or more select lines exceeds the reference signal by outputting a logic value.

45. The electronic system of claim 43, wherein some of the select lines are word lines that intersect bit lines, wherein each intersection of a word line and a bit line defines a memory cell of the memory device.

46. The electronic system of claim 45, wherein the memory cells are arranged in rows and columns.

47. The electronic system of claim 46, wherein each column of the array includes a string of memory cells connected together in series between a pair of other of the select lines.

48. The electronic system of claim 43, wherein the signal indicative of a current drawn by one or more select lines is either a voltage or a current and the reference signal is a reference voltage or a reference current.

49. An electronic system, comprising:
a processor; and
a memory device coupled to the processor and comprising:
a memory array having a plurality of select lines, wherein some of the plurality select lines intersect bit lines, wherein each intersection of a select line and a bit line defines a memory cell of the array; and
test circuitry coupled to each of the plurality of select lines, the test circuitry comprising:
a current mirror having a reference leg and a mirror leg, wherein the reference leg of the current mirror is coupled to each of the plurality of select lines;
a first n-channel field-effect transistor having a drain and a gate coupled to the mirror leg of the current mirror and a source coupled to a ground potential node; and
a second n-channel field-effect transistor having a gate coupled to the gate of the first n-channel field-effect transistor, a source coupled to a ground potential node and a drain; and
a comparator for comparing a current draw thru the second n-channel field-effect transistor to a reference current, and providing an output signal indicative of whether the current draw thru the second n-channel field-effect transistor is greater than the reference current.
